(19) United States
(12) Patent Application Publication
(10) Pub. No.: US 2015/0077170 A1
(43) Pub. Date: Mar. 19, 2015

(54) EFFICIENT WAKEUP OF POWER GATED DOMAINS THROUGH CHARGE SHARING AND RECYCLING

(71) Applicant: International Business Machines Corporation, Armonk, NY (US)

(72) Inventors: Pradip Bose, Yorktown Heights, NY (US); Alper Buyuktosunoglu, White Plains, NY (US); Hans Jacobson, White Plains, NY (US); Victor Zyuban, Yorktown Heights, NY (US)

(73) Assignee: International Business Machines Corporation, Armonk, NY (US)

(21) Appl. No.: 14/026,418

(22) Filed: Sep. 13, 2013

(51) Int. Cl. H03K 17/22

(52) U.S. Cl. CPC H03K 17/22
USPC 327/427

(57) ABSTRACT

A mechanism is provided for an integrated circuit with power gating. A power header switch is configured to connect and disconnect any circuits to a common voltage source. A powered off circuit is disconnected from the common voltage source. A first capacitor and a second capacitor are configured to supply wakeup electrical charge to a given circuit of the circuits. The first capacitor and the second capacitor are connectable to the given circuit and the powered off circuit. A controller is configured to controllably connect the first capacitor and/or the second capacitor to the given circuit in order to supply the wakeup electrical charge to the given circuit, when the powered off circuit was previously connected to the first capacitor and/or the second capacitor.

### BACKGROUND

The present invention relates to microprocessor core wake up, and more specifically, to waking up a power gated microprocessor core by sharing and recycling charge from a microprocessor core being power gated.

Power gating is a technique used in integrated circuit design to reduce power consumption, by shutting off the flow of current to blocks of the circuit that are not currently in use. Power gating also reduces stand-by or leakage power.

Power gating affects design architecture of the integrated circuit, and increases time delays, as power gated modes have to be safely entered and exited. Architectural trade-offs exist between designing for the amount of leakage power saving in low power modes and the energy dissipation to enter and exit the low power modes. Shutting down the blocks can be accomplished either by software or hardware. Driver software can schedule the power down operations, or hardware timers can be utilized. A dedicated power management controller is another option.

### SUMMARY

According to an embodiment, an integrated circuit with power gating is provided. The integrated circuit includes a power header switch configured to connect and disconnect any one of a plurality of circuits to a common voltage source, where a powered off circuit is disconnected from the common voltage source. A first capacitor and a second capacitor are configured to supply wakeup electrical charge to a given circuit of the plurality of circuits. The first capacitor and the second capacitor are connectable to the given circuit and the powered off circuit. A controller is configured to controllably connect at least one of the first capacitor and the second capacitor to the given circuit in order to supply the wakeup electrical charge to the given circuit, when the powered off circuit was previously connected to at least one of the first capacitor and the second capacitor.

According to an embodiment, a method of operating an integrated circuit with power gating is provided. The method includes configuring a power header switch to connect and disconnect any one of a plurality of circuits to a common voltage source, where a powered off circuit is disconnected from the common voltage source. A first capacitor and a second capacitor are controlled to supply wakeup electrical charge to a given circuit of the plurality of circuits. The first capacitor and the second capacitor are connectable to the given circuit and the powered off circuit. A controller is configured to controllably connect at least one of the first capacitor and the second capacitor to the given circuit in order to supply the wakeup electrical charge to the given circuit, when the powered off circuit was previously connected to at least one of the first capacitor and the second capacitor.

According to an embodiment, a method of operating an integrated circuit with power gating is provided. The method includes turning off a first power domain on the integrated circuit by disconnecting the first power domain from a common voltage source, where the first power domain includes a first circuit and a first capacitor connected to the first circuit. A second power domain on the integrated circuit includes a second circuit and a second capacitor connected to the second circuit. Responsive to the second power domain being turned off and in preparation to turn on the second power domain, the second power domain is connected to the first power domain to transfer electrical charge from the first power domain into the second power domain.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 illustrates a multistage multicore wakeup process of an integrated circuit.

FIG. 2 illustrates circuits sharing and recycling power in the integrated circuit according to an embodiment.

FIG. 3 illustrates circuits sharing and recycling power in the integrated circuit according to an embodiment.

FIG. 4 illustrates circuits sharing and recycling power in the integrated circuit according to an embodiment.

FIG. 5 illustrates a method of operating the integrated circuit with power gating according to an embodiment

FIG. 6 illustrates a method of operating the integrated circuit with power gating according to an embodiment

FIG. 7 is a block diagram that illustrates an example of a computer (computer setup) having capabilities, which may be included in and/or combined with embodiments.

### DETAILED DESCRIPTION

Embodiments relate to integrated circuits and examples disclosed may be applied, for example, to a general purpose multicore processor chip (G) attached to an accelerator (off-load engine) chip A. Due to the coordinated “back-and-forth” execution across such a system, in which the spawning of accelerator threads by the main processor threads causes idle hardware G-threads on the processor side, and in which termination of accelerator threads causes idle hardware A-threads, there are significant opportunities for power gating of core/accelerator resources on both the G and A chips.

One of the known sources of energy waste in such a G-A system with power gating capability is the fact that the power gated resource (e.g., a core) loses its charge through a leakage process, via the effective resistor-capacitor (RC) path to ground presented to the resource once it is cut off from the power supply via the header transistor switch(es).

Embodiments provide techniques that minimize such energy waste by using the available charge of the power gated core (i.e., circuit being turned off) to wake up other resources (i.e., cores) that may be invoked for system computational needs. Also, embodiments provide a technique to accelerate the wakeup process for any given power-gateable domain (e.g. core or accelerator).

For example, embodiments utilize the charge available from a recently power gated circuit to charge up a separate circuit that is predicted for usage in the near future. The controller includes predictive control logic that determines when to pre-charge the circuit that is being subject to power gating.

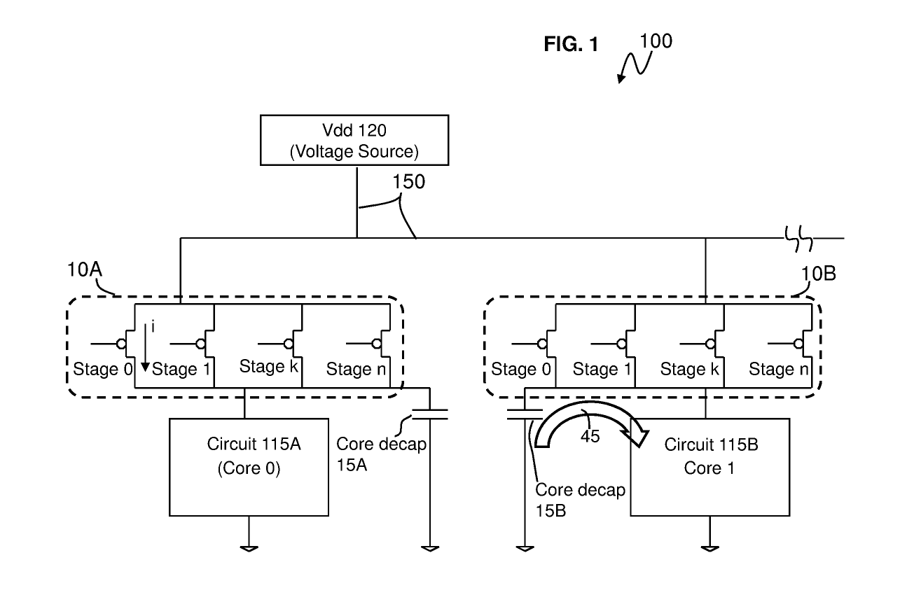

FIG. 1 illustrates a multistage multicore wakeup process of an integrated circuit 100. State of the art integrated systems may utilize core or sub-core (accelerator lane) level power gating. That is, one or more cores (or sub-cores) on a multicore processor can be turned off to conserve power. Also, there is the significant wakeup time for such a resource (i.e., core or sub-core), once it is determined that the resource is needed back as part of the available compute resources.

In FIG. 1, a common voltage source 120 is connected to header switches 10A and 10B. The common voltage source 120 may also be referred to as Vdd or common power supply.

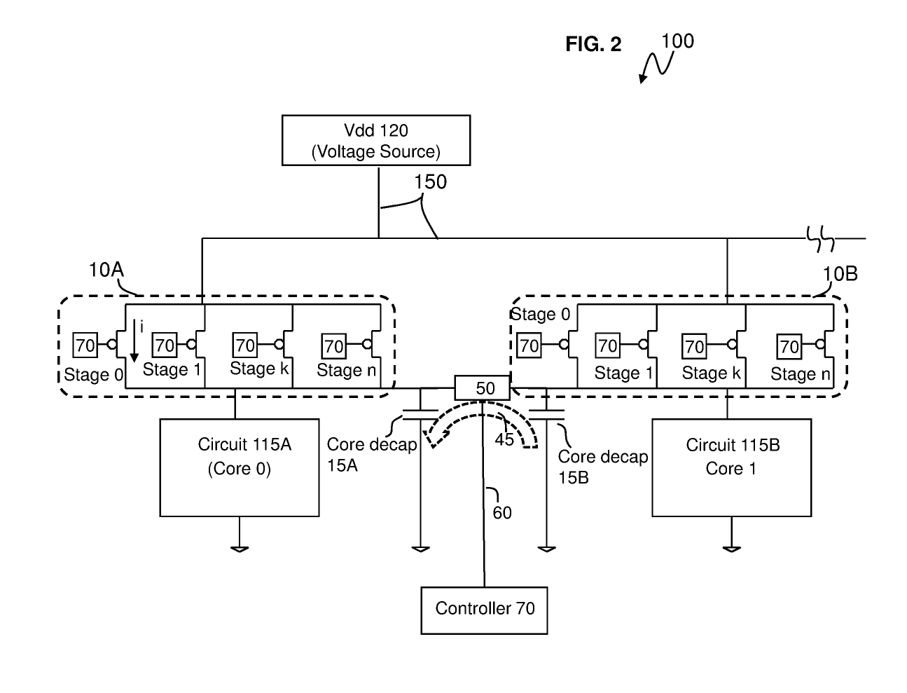

The header switches 10A and 10B may generally be referred to as header switches 10. Also, the header switches 10A and 10B are known as power gating header devices or headers. The header switch 10A collectively includes stage 0 header transistor, stage 1 header transistor, stage k header transistor, and stage n header transistor (all of which have their respective gate terminals (base terminal if bipolar transistors are used for the power switch) connected a controller 70 for receiving control signals (i.e., gate voltages) that individually turn on and turn off each respective stage 0 through stage n header transistor as shown in FIG. 2-4). The sources of the stage 0 through stage n header transistors are respectively connected to the voltage source 120 to supply power to circuit 115A through their respective drains.

Similarly, the header switch 10B collectively includes stage 0 header transistor, stage 1 header transistor, stage k header transistor, and stage n header transistor (all of which have their respective gate terminals connected the controller 70 for receiving control signals (i.e., gate voltages) that individually turn on and turn off each respective stage 0 through stage n header transistor as shown in FIG. 2-4). The sources of the stage 0 through stage n header transistors are respectively connected to the voltage source 120 to supply power to circuit 115B through their respective drains.

Circuits 115A and 115B respectively may be core 0 and core 1 on a microprocessor as the integrated circuit 100. Circuit 115A has decoupling capacitor 15A (core decap), and the circuit 115A may include internal capacitance. One plate of the decoupling capacitor 15A is connected to both circuit 115A and the drain terminals of stage 0 through n header transistors of header switch 10A.

Similarly, circuit 115B has decoupling capacitor 15B (core decap), and the circuit 115B may include internal capacitance. One plate of the decoupling capacitor 15B is connected to both circuit 115B and drain terminals of stage 0 through n header transistors of header switch 10B.

It is assumed that circuit 115A (core 0) is waking up from a power gated state (i.e., core 0 is being turned on/powered on), and circuit 115B is being turned off (i.e., core 1 is being powered gated). The charge (i.e., leaking current 45 shown as block circular arrow) stored in the decoupling capacitor 15B (also referred to as power grid capacitance) of core 1 is discharged through the (leaking) core 1 to ground, which leads to the energy being dissipated as wasted heat. As an example, the leakage current 45 may be in the range from 100 milliamps to 10 Amps. Note that the charge in the internal capacitance of circuit 115B also leaks to ground. The power grid node (power domain) of circuit 115B (core 1) is the decoupling capacitor 15B and the circuit 115B itself (including its internal capacitance). The power grid node of circuit 115B remains temporarily charged up to voltage VDD of voltage source 120 even when the header switch 10B is turned off (i.e., during power gating). After being disconnected from the power supply 120, the power grid node (of circuit 115B) starts loosing its charge due to the leakage current though transistors comprising circuit 115A. Through this discharge process, the electrical energy stored in the (capacitance) capacitor 15A is dissipated in the form of the heat in the transistors of circuit 115A. The time duration of the decoupling capacitance discharge process can range between 100 microseconds (μs) and tens of seconds, depending on the magnitude of the decoupling capacitance and the leakage current. At the end of the discharge process all of the electrical charge stored in the decoupling capacitance is lost (that is dissipated as heat). Before the power grid of circuit 115B (i.e., the decoupling capacitor 15B along with the internal capacitance of circuit 115B) discharges, this electrical charge stored in the decoupling capacitance can be made available to power up (pre-charge) circuit 115A (when circuit 115A is predicted to be turned on) according to embodiments (as discussed further below). In most practical scenarios, if the two circuits involved in the charge recycling process have the same amount of decoupling capacitance, then approximately half of the electrical charge stored in the decoupling capacitance can be transferred to the other circuit. This process of making the electrical charge of a recently power gated circuit available for the powering up of another power gated circuit is referred to as the charge transfer, charge sharing, and/or charge recycling in this disclosure. The electrical charge transferred to the circuit undergoing the power-on process is referred to as “wakeup electrical charge” and/or “wakeup charge” in this disclosure. In order for the charge recycling process to be effective, the circuit from which the electrical charge is recycled must be in the power gated state for no longer than a predefined interval of time (ranging from a fraction of a microsecond to tens of milliseconds), before the charge recycling is initiated. The maximum length of the time interval which may (but not necessarily) limit the effectiveness of the charge recycle depends on the ratio between the amount of the decoupling capacitance and the magnitude of the leakage current through the transistors in the circuit. The leakage current, in turn, depends on the temperature, voltages and device threshold variations. Therefore, the maximum time between entering the power gated state and initiating the charge recycling process needs to be established individually for each circuit, taking into account both the electrical parameters and environmental variables. In this disclosure the terms “recently power gated circuit”, “just power gated circuit”, and “just power gated domain” refer to a power gated circuit where the electrical charge on the power grid and the decoupling capacitance is still holding at least one quarter to half of its original value, so that the charge recycling process can transfer a significant (predefined) fraction of the electrical charge to the other circuit.

FIGS. 2, 3, and 4 illustrate modifications to the integrated circuit 100 shown in FIG. 1, according to embodiments. Embodiments provide apparatuses for reducing the energy waste caused by leakage-based draining of charge from the power gated resource and also for (incidentally) reducing the wakeup time of a core/circuit.

FIG. 2 illustrates circuits 115A and 115B sharing and recycling electrical charge in the integrated circuit 100 according to an embodiment.

A coupling element 50 is connected to both the circuit 115A and its decoupling capacitor 15A. Also, the coupling element 50 is connected to both the circuit 115B and its decoupling capacitor 15B. The coupling element 50 provides programmable connection across any pair of power gateable domains/power gateable power grids. The circuit 115A and its decoupling capacitor 15A are the first power gateable domain, and the circuit 115B and its decoupling capacitor 15B are the second power gateable domain.

The decoupling capacitors 15A and 15B are designed with a charge-holding capability implemented as one or more on-chip (e.g., on the chip of the microprocessor as the integrated circuit 100) decoupling capacitors, which may be field effect transistor (FET) capacitors, deep-trench capacitors, and/or package-mounted capacitors or board mounted capacitance.

According to embodiments, the charge from the recently power gated domain (e.g., circuit 115B) is recycled and shared to another domain (e.g., circuit 115A) that needs to be turned on within a predetermined time of turning off the power gated domain.

A controller 70 is configured to turn on the coupling element 50 that allows current to flow from circuits 115B (being turned off, i.e., power gated) and its decoupling capacitor 15B to circuit 115A and its decoupling capacitor 15A (being turned on and/or about to be turned on in the near future (e.g., less than 60 seconds)). The controller 70 may be a hardware device and/or software which contains (and/or receives) domain-specific predictive control logic that orchestrates the charge sharing and recycling process across power-gateable domains, by appropriately enabling and disabling the control switches (implemented as coupling element 50 along with coupling elements 51, 52, 53, and 54 discussed herein) according to embodiments.

Also, note the controller 70 is connected to the individual gates of stage 0 through stage n header transistors in both header switches 10A and 10B, to respectively turn on and off the individual header transistors according to the logic of the controller 70, for operating the microprocessor.

For example, the controller 70 operates as a power-up sequencer for circuit 115A, and the controller 70 operates as a power-up sequencer for circuit 115B. The respective power-up sequencers power on and/or power off the respective stage 0 through stage n header transistors in header switch 10A and the respective stage 0 through stage n header transistors in header switch 10B. The circuits 115A and 115B are representative of circuits on any type of integrated circuit 100 such as a microprocessor. The circuit 115A may be core 0 and the circuit 115B may be core 1 on a single microprocessor connected to voltage Vdd of the common source 120. It is understood that the microprocessor is not limited to two cores, and additional cores/circuits are on the microprocessor and connectable to the common voltage source 120 as explained herein.

The controller 70 may be implemented as discrete logic circuits having logic gates for implementing logic functions, an application specific integrated circuit (ASIC) having appropriate combinational logic gates, programmable gate arrays (PGA), a field programmable gate array (FPGA), etc., to function as discussed herein. Also, the controller 70 may be firmware (such as a hypervisor), a minicontroller, or a state machine all of which include logic (mini-software and/or hardware logic circuits) for operating as discussed herein to control the various transistors. The controller 70 may also run as part of the operating system.

When a circuit/core is being powered up (turned on), a significant amount of electrical charge is required to be supplied to the power grid of the circuit/core being powered up. Because of the high inductance path from the global power grid 150 to the voltage source 120 (power supply), the charge cannot be supplied instantly from the voltage source 120 (power supply). Therefore, if the core 0 is powered up too quickly, the charge needed to power up the core 0 grid is being supplied by the power grid of other running cores (such as circuit 115B of core 1) on the same chip. This large draw of current causes noise on the power grid of the running cores (i.e., on the power grid header switch 10B of circuit 115B), potentially leading to the risk of a failure in one (e.g., circuit 115B) of the running cores. As an example of computing the amount of voltage noise that could be introduced on the power grids of the running cores when one of the cores is powered up while turning on all of the power switch transistors simultaneously, consider the following scenario. The processor chip has two cores, and each core has 0.1 micro Farad (μF) of total capacitance connected to the power grid including the decoupling capacitance and the internal capacitance of the circuits. The nominal operating voltage is Vdd=1.0V and the nominal current consumption of each core is 10 amps. The total gate width of the CMOS (complementary metal-oxide-semiconductor) transistors comprising the power switch is 1 meter, capable of supplying the nominal current to each core at 10 millivolts of voltage drop between the source and drain terminals of the header switch CMOS transistors. Suppose that when core 0 is power gated, the voltage at its power grid is reduced to 0.1V due to the leakage current through the circuits of core 0 to the ground. In this example, simultaneously turning on all of the power switch transistors (of core 0) will result in an initial current (draw) of 1000 amps flowing through the power switch transistors into the decoupling capacitance and the internal capacitance of core 0. The electrical inductance of the chip package (e.g., the chip/integrated circuit 100) limits the rate of increase in the current flowing from the external voltage regulator into the circuit. For a package electrical inductance of 1 picoHenry (pH), the rate of current increase of 10 A per nanosecond creates a voltage drop of 10 millivolts across the package electrical inductance. Thus, because of the electrical inductance of the package the external power supply (e.g., voltage source 120) can only supply approximately 10 A of current out of the 1000 A (which is 1%) of current flowing through the power switch into the decoupling and internal capacitance of core 0 within the first nanosecond after turning on the power switch transistors. The remaining 99% of current is supplied by all other capacitances connected to the source terminals of the power switch transistors, including the decoupling capacitance of the running core 1 (and other running cores 5). If the total capacitances of core 0 and core 1 are equal and no other significant decoupling on-chip capacitance is connected to the net 150, then the voltage at core 1 will drop to approximately ½ Vdd. If the processor chip has 20 cores connected to the same power supply net, then the voltage noise caused by turning on one of the power gated cores introduces the noise of approximately 1/20 Vdd, or 50 mV. In typical microprocessor design the maximum voltage noise on the power grid that can be tolerated without impacting the operation of the running cores is in the range of 10 mV. This example clearly demonstrates that simultaneously turning on all power switch transistors of a power gated core introduces a significant level of power supply noise of the running cores, potentially leading to failures in the running cores.

Therefore, in the state of the art in order to power up a core (e.g., core 0), the controller 70 (power-up sequencer) generates control signals for the header transistors of the header switch 10A, turning them on in stages. For example, turning on stage 0 header transistor is the first stage, turning on stage 1 header transistor is the second stage, turning on stage K header transistor is the third stage, and turning on stage n header transistor is the last stage (in respective header switches 10A and 10B, where each transistor is larger than the previous (i.e., allowing more current to flow)). Typically, a small section of the header switch 10A is turned during the first stages of the wake-up sequence in order to bring up the power grid of the core from the power-down level to a level close to the external power supply (i.e., close to Vdd of voltage source 120), before the next, bigger stage of the header switch is turned on. This multistage process for powering up a core (e.g., core 0) leads to a significant increase in the power-up latency.

Further details of the latency are provided as an example of waking up circuit 115A (core 0) after having been turned off/powered down. When waking up the circuit 115A, the controller 70 first enables the stage 0 (first) header transistor, and then waits until the introduced noise on the power grid (i.e., on connections of header switch 10B) settles. Then, the controller 70 enables the stage 1 (second) header transistor and then waits until the introduced noise on the power grid (i.e., on connections of header switch 10B) settles. Next, the controller 70 enables stage K (third) header transistor and then waits until the introduced noise on the power grid settles. Finally, the controller 70 enables the stage n last (biggest) header transistor. These steps/stages take time to walk through and so introduce latency in waking up a power gated circuit (i.e., the power gated circuit 115A).

The following example shows the typical latency of powering up a power gated core (i.e., powered off core) without introducing a significant amount of noise on the power grid of the running cores. In order to power-up the core the power switch transistor is partitioned into four to ten stages (note that four stages are shown in power switch transistors 10A and 10B). The total gate width of transistors in the first stage is typically set to 0.01% to 0.1% of the total gate width of the transistors of the power switch (e.g., power switch transistors 10A). Limiting the gate width of the transistors in the first stage to 0.1% reduces the current flowing into the decoupling capacitance of the power gated core 0 from 1000 amps in the earlier example to approximately lamp. This amount of current increase can be provided by the off-chip power supply within 0.1 nanosecond without exceeding the 10 mV limit on the allowed power supply noise. The total transistor sizes of the second stage of the power switch can be set to be a factor of 2× to 10× of the first stage, and so on. Thus, in order to turn on 100% of the power switch gate width, starting with 0.01% of the gate width at stage 1 and increasing the gate width by factor of 2× between every two stages, the total of 13 stages are required (computed as a base-2 logarithm of the ratio of the total gate width to the gate width of the first stage). Using a more aggressive turn-on sequence, starting with 0.01% of the gate width at stage 1 and increasing the gate width by factor of 4× between every two stages, the total of 7 stages are required (computed as a base-4 logarithm of the ratio of the total gate width to the gate width of the first stage). In order to avoid the interaction between consecutive stages in the power-up process, the turning on of any two consecutive stages must be separated by a time interval of between hundreds of nanosecond to tens of microseconds, resulting in a total wake up latency of up to hundreds of microseconds.

As discussed herein, embodiments reduce the latency of the core wakeup process discussed above and provide an efficient use of available charge.

A scenario is provided as an example in which initially circuit 115A (core 0) is power gated (i.e., stage 0 through stage n header transistors of header switch 10A are turned off and thus disconnect the circuit 115A (core 0) and its decoupling capacitor 15A from the voltage source 120). Circuit 115B (core 1) is up and running (i.e., stage 0 through stage n header transistors of header switch 10B are turned on such that circuit 115B (and its decoupling capacitor 15B) receives power from the common voltage source 120).

Next, the controller 70 is configured to power off (or begin powering offer) the circuit 115B (core 1) by turning off the header switch 10B (i.e., turning off the stage 0 through stage n header transistors connected to circuits 115B). At this point, the circuit 115B is disconnected from the voltage source 120 (via header switch 10B), and the coupling element 50 (e.g., transistor 50) has not been turned on by the controller 70. Based on the controller 70 recognizing that circuit 115A is ready to be turned on and/or based on predictive logic (in controller 70) determining that circuit 115A should be turned on, the controller 70 is configured to turn on the coupling element 50 to connect circuit 115B (and its decoupling capacitor 15B) just turned off to circuit 115A (and its decoupling capacitor 15A) that is ready to be turned on and/or is to be turned on in the near future (e.g., less than 6 milliseconds). In one case, the controller 70 is configured to determine that circuit 115A is waking up from the power gated state in close proximity (e.g., within 1-6 milliseconds) to when the circuit 115B is being turned off. In one case, the controller 70 is configured delay turning off power (i.e., turning off header transistors is the header switch 10B) to the circuit 115B (by e.g., 3-15 milliseconds) in order that a time window of (within 1-6 milliseconds) is established between when circuit 115A is to be turned on and when circuit 115B is turned off.

The controller 70 includes (and/or is connected to another circuit) predictive logic (which can be hardware logic circuits and/or software implementing logic) that determines (in advance) when a circuit (e.g., circuits 115A and/or 115B) is to be or should be waken up. This determination to wake up the circuit, such as the circuit 115A, may be based on past utilization history of the integrated circuit (microprocessor), based on the current state of N circuits/cores of the microprocessor, based on when utilization of the circuits/cores of the microprocessor is high, based on knowledge of the operating system scheduling queue (i.e., scheduling of threads for the circuits/cores of the microprocessor), and/or based on the length of time in which the circuit has already been turned on. It is understood that additional information may be utilized to predict that the power gated circuit/core needs to be pre-charged in anticipation of waking up the power gated circuit/core.

To share or recycle the remaining charge stored in the circuit 115B and in decoupling capacitor 15B when circuit 115B is turned off, the controller 70 is configured to turn on (i.e., activate) the coupling element 50. In one case, the coupling element is a transistor with its gate connected to the controller 70, its source connected circuit 115B, and its drain connected to circuit 115A, such that current flows from both circuit 115B and decoupling capacitor 15B to circuit 115A and its decoupling capacitor 15A. These current results in the transfer of charge from circuit 115B to circuit 115A. In the prior art implementation without charge recycling 100% of the electrical charge in circuit 115B is dissipated as heat. However, the current embodiment allows a significant fraction of the electrical charge of circuit 115B to be recycled for powering up circuit 115A, thereby reducing the amount of electrical charge consumed from the power supply. Thus, the charge recycling process of the current embodiment leads to reduced energy consumption for operating the electrical system 100. Note that the header transistors in header switches 10A and 10B are both turned off when the controller 70 turns on the coupling element 50 to share charge (e.g., from circuit 115B to circuit 115A).

Prior to stage 0 through stage n header transistors of header switch 10A being turned on to connect voltage source 120 to the circuit 115A, the circuit 115A (and decoupling capacitor 15A) receives current from circuit 115B (and decoupling capacitor 15B) to charge the circuit 115A (and decoupling capacitor 15A) to approximately ½ voltage of the circuit 115B (and decoupling capacitor 15B). The voltage at the circuit 115A at the end of the charge recycling process depends on the ratio of the decoupling capacitances on circuits 115A and 115B. For example, if the charge recycling process is initiated within a few microseconds after the circuit 115B is turned off, then the voltage of circuit 115B at the beginning of the charge recycling process is still very close to the power supply value of the voltage source 120 (Vdd). If circuits 115A and 115B are similar and have the same amount of the decoupling capacitance, then the circuit 115A is charged to approximately ½ Vdd by activating/connecting the coupling element 50 to recycle and share the current in circuit 115B (just turned off) with the circuit 115A (that is to be turned on). When the charge recycling (from circuit 115B to circuit 115A) is complete (that is when the voltages at the circuits 115A and 115B are within the predefined number of millivolts of each other), the controller 70 is configured to turn off the coupling element 50 thus disconnecting circuit 115A (and its decoupling capacitor 15A) from circuit 115A (and its decoupling capacitor 15B). The controller 70 may be configured to determine (e.g., measure) when the voltage across each of the circuits 115A and 115B and decoupling capacitors 15A and 15B have reached a steady state (such as when the voltage difference between capacitors 15A and 15B is smaller than 10 mV); accordingly, the controller 70 turns off the coupling element 50 once the steady state reached. In one case, the controller 70 may be configured (via a timer) to allow the connection with coupling element 50 to remain for a predetermined about of time (e.g., 10 milliseconds (ms), 20 ms, and/or 1-5 seconds) before disconnecting/turning off the coupling element 50. Tuning off/disconnecting the coupling element 50 forms/causes an open circuit between circuit 115A and circuit 115B, while turning on/connecting the coupling element 50 completes the circuit between circuits 115A and 115B (along with their respective decoupling capacitors 15A and 15B). The controller 70 turns the coupling element 50 on (i.e., activates) and off (i.e., deactivates) via a control signal 60 (which can provide gate voltage to turn on the transistor 50).

Even before the header switch 10A has been turned on to supply power to the circuit 115A (and its decoupling capacitor 15A) from common voltage source 120, the circuit 115A has been pre-charged to approximately ½ voltage Vdd by recycling power from circuit 115B. Once the decoupling element 50 is turned off by the controller 70 (thus disconnecting circuits 115A from 115B), the stage 0 through stage n header transistors of header switch 10A are turned on by the controller 70 (e.g., all at once) within a time window (e.g., less than 3 milliseconds, less than 5 milliseconds, and/or within 1-10 milliseconds after the coupling element 50 has been turned off). Notice that the transfer of the electrical charge through the coupling element 50 occurs without consuming current from the power supply 120 and without increasing the current flowing from the power supply 120 through the current delivery network 150 which may have a significant electrical inductance. Therefore, no extra noise is introduced on the power supply grid 150 by the charge recycling process. For this reason, it is safe to make the charge recycling process occur fast, thereby reducing the latency of initial steps of the power-up process. To further reduce the latency of the power-up process, since the circuit 115A (and its decoupling capacitor 15A) have been pre-charged to ½ Vdd, the controller 70 may only turn on stage n header transistor (which is the largest transistor) of header switch 10A without having to traverse through the lower stages (i.e., without having to sequentially turn on stage 0 through stage k before then turning on stage n header transistors). Also, the controller 70 may turn on all stages 0 through n header transistors (of header switch 10A) at one time (without sequentially turning them on in stages). The latency of having to turn on one stage and wait before turning on subsequent stages is removed, and the residual power/charge on the circuit 115B is efficiently recycled and shared.

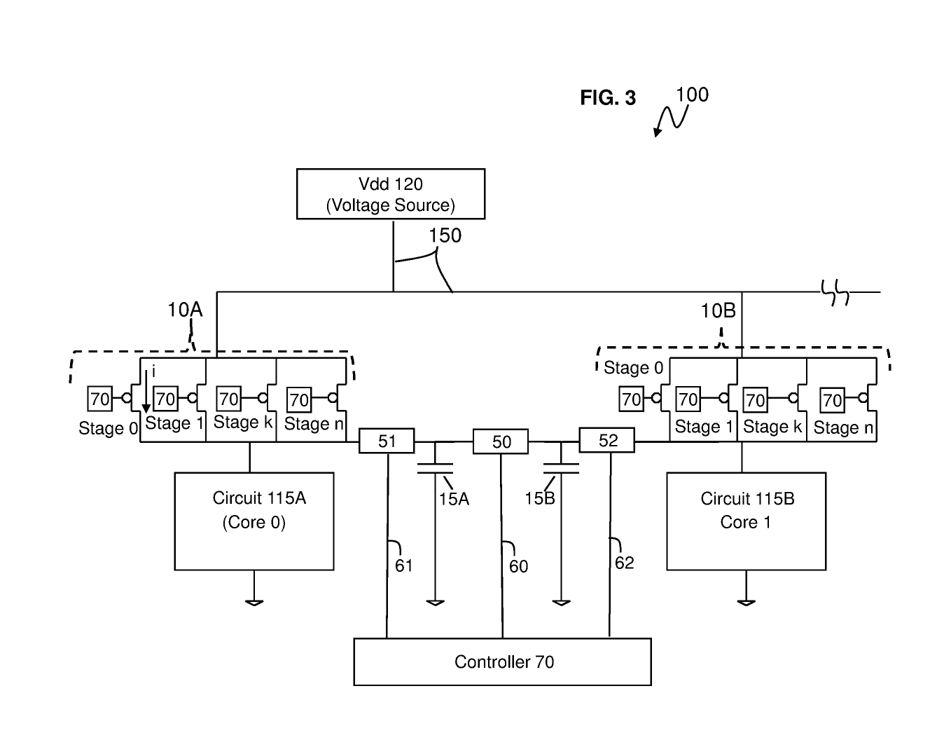

FIG. 3 illustrates another example of the circuits 115A and 115B sharing and recycling power in the integrated circuit 100 according to an embodiment. In FIG. 3, the integrated circuit 100 now includes coupling elements 51 and 52 in addition to coupling element 50.

In FIG. 3, the coupling element 51 connects the circuit 115A to the decoupling capacitor 15A, and the coupling element 52 connects the circuit 115B to the decoupling capacitor 15B. The controller 70 is configured to turn the coupling element 51 on (i.e., activates) and off (i.e., deactivates) via a control signal 61 (which can provide gate voltage to turn on the transistor 51). Similarly, the controller 70 is configured to turn the coupling element 52 on (i.e., activates) and off (i.e., deactivates) via a control signal 62 (which can provide gate voltage to turn on the transistor 52).

Various scenarios are provided below as options for the controller 70 to control (i.e., turn on and off) the coupling elements 50, 51, and 52, when recycling and sharing charge.

Initially, transistor 50 is turned off when both circuits 115A and 115B are running. The stage 0 through stage n headers transistors in header switches 10A and 10B are turned on, as both circuits 115A and 115B are running and connected to voltage source 120. Also, both coupling elements 51 and 52 are turned on. As such, both decoupling capacitors 15A and 15B are charged to voltage Vdd of voltage source 120.

When power gating circuit 115A, the controller 70 is configured to turn off coupling element 51 and (then) to turn off stage 0 through stage n header transistors of the header switch 10A. Now, the decoupling capacitor 15A is charged to voltage Vdd (from voltage source 120) and floating. The decoupling capacitor 15A holds its charge for a long time since it is not electrically connected to the transistors in circuit 115A. The charge in circuit 115A will leak out to ground (GND).

At this point, circuit 115B is running (i.e., connected to common voltage source 120 via header switch 10B), coupling elements 50 and 51 have been turned off, and coupling element 52 is turned on.

When the controller 70 is going to power gate circuit 115B, the controller 70 turns off the coupling element 52 and (then) turns off stage 0 through stage n header transistors of the header switch 10B. The decoupling capacitor 15B is charged to voltage Vdd (from voltage source 120) and floating. The decoupling capacitor 15B holds its charge for a long time. The charge in circuit 115B (eventually) leaks out to ground (GND). At this point, all coupling elements 50, 51, and 52 are turned off. To continue the illustration, example scenarios are provided below for explanation purposes. These scenarios may be combined as would be understood by one skilled in the art. For example, one scenario may occur once, then the next scenario may occur, the following scenario may occur, some scenarios may repeat, and so forth.

Scenario 1

When the controller 70 is ready to turn on (wake up) the circuit 115A and/or predicts that it is soon time, the decoupling capacitor 15A still has its charge. While the header switch 10A, the coupling element 50, and the coupling element 52 all remain off, the controller 70 is configured to turn on coupling element 51 (optionally the coupling element 50 may also be turned on) to pre-charge the circuit 115A. This is considered pre-charging the circuit 115A because the header switch 10A has not been turned on to connect the circuit 115A to the common voltage source 120. Turning on coupling element 51 causes current to flow from decoupling capacitor 15A to circuit 115A such that circuit 115A (e.g., internal capacitance) is charged. When decoupling capacitor 15A is charged to voltage Vdd, the decoupling capacitor 15A charges (i.e., pre-charges) the circuit 115A to a level which is a fraction of the voltage at the power supply Vdd. The level to which circuit 115A is precharged depends on the ratio of the decoupling capacitance 15A and the internal capacitance of circuit 115A. The practical range of the precharge voltage level is between ½ VDD and 9/10 Vdd. The pre-charge process completes before the header switch 10A connects the circuit 115A to the voltage source 120.

Since the circuit 115A has been pre-charged to a level which is a significant fraction of the voltage at the power supply (such as in the range ½- 9/10 of Vdd) by taking charge from the decoupling capacitor 15A, the controller 70 may only turn on stage n header transistor (which is the largest transistor) of header switch 10A without having to traverse through turning on the lower stages (i.e., without having to sequentially turn on stage 0 through stage k header transistors before then turning on stage n header transistor). Also, the controller 70 may turn on all stages 0 through n header transistors (of header switch 10A) at one time (without sequentially turning them on in stages). The latency of having to turn on one stage and wait before turning on subsequent stages is removed, and the residual power/charge on the decoupling capacitor 15A is efficiently recycled and shared.

Now, the circuit 115A is running, and the controller 70 is also configured to wake up the circuit 115B from its power gated state by first pre-charging the circuit 115B. When the controller 70 is ready to turn on (wake up) the circuit 115B and/or predicts that it is soon time, the decoupling capacitor 15B still has its charge. While the header switch 10B and the coupling element 50 both remain off, the controller 70 is configured to turn on coupling element 52 to pre-charge the circuit 115B. This is considered pre-charging the circuit 115B, because the header switch 10B has not been turned on to connect the circuit 115B to the common voltage source 120. Turning on coupling element 52 causes current to flow from decoupling capacitor 15B to circuit 115B such that circuit 115B (e.g., internal capacitance) is charged. When decoupling capacitor 15B is charged to voltage Vdd, the decoupling capacitor 15B charges (i.e., pre-charges) the circuit 115B to a level which is a significant fraction of the voltage at the power supply (such as in the range ½- 9/10 of Vdd) which is before the header switch 10B connects the circuit 115B to the voltage source 120.

Since the circuit 115B has been pre-charged to a significant fraction of the voltage at the power supply by taking charge from the decoupling capacitor 15B, the controller 70 may only turn on stage n header transistor (which is the largest transistor) of header switch 10B without having to traverse through turning on the lower stages (i.e., without having to sequentially turn on stage 0 through stage k header transistors before then turning on stage n header transistor). Also, the controller 70 may turn on all stages 0 through n header transistors (of header switch 10B) at one time (without sequentially turning them on in stages). The latency of having to turn on one stage and wait before turning on subsequent stages is removed, and the residual power/charge on the decoupling capacitor 15B is efficiently recycled and shared. Notice that the transfer of the electrical charge through the coupling elements 50 and 51 occurs without consuming current from the power supply 120 and without increasing the current flowing from the power supply 120 through the current delivery network 150 which may have a significant electrical inductance. Therefore no extra noise is introduced on the power supply grid 150 by the charge recycling process. For this reason, is safe to make the charge recycling process occur fast, thereby reducing the latency of initial steps of the power-up process.

Scenario 2

In this scenario, current is taken from both decoupling capacitors 15A and 15B to charge the circuit 115A. For example, when the controller 70 is ready to turn on (wake up) the circuit 115A and/or predicts that it is soon time (note the circuit 115B is turned off), the decoupling capacitors 15A and 15B still have their respective charge. In this case, the header switch 10A and coupling element 52 are both off, the controller 70 is configured to turn on coupling element 51 and coupling element 50 to pre-charge the circuit 115A. Again, the header switch 10A has not been turned on to connect the circuit 115A to the common voltage source 120. Turning on coupling element 51 connects the circuit 115A to the decoupling capacitor 15A, and (then) turning on coupling element 50 also connects capacitor 15B to the circuit 115A. (Note that in scenario 1 only decoupling capacitor 15A was connected to the circuit 115A.) Turning on coupling elements 50 and 51 cause current to flow from both decoupling capacitors 15A and 15B to circuit 115A such that circuit 115A (e.g., internal capacitance) is charged. When decoupling capacitors 15A and 15B are both the same size and charged to voltage Vdd, the decoupling capacitors 15A and 15B charge (i.e., pre-charges) the circuit 115A to a significant fraction of the voltage at the power supply Vdd which depends on the ratio of the decoupling capacitance and the internal capacitance of circuit 115A. In scenario 2 a higher level of precharge voltage is achieved than in scenario 1. For illustration purpose assume that the internal capacitance of circuits 115A, 115B equals the decoupling capacitance 15A and 15B. Then as a result of the charge sharing process, the circuit 115A is precharged to ⅔ Vdd, all of which occurs before the header switch 10A connects the circuit 115A to the voltage source 120. The circuit 115A has wakened up part of the way.

Since the circuit 115A has been pre-charged to ⅔ Vdd by taking charge from both the decoupling capacitors 15A and 15B, the controller 70 may only turn on stage n header transistor (which is the largest transistor) of header switch 10A without having to traverse through turning on the lower stages (i.e., without having to sequentially turn on stage 0 through stage k header transistors before then turning on stage n header transistor). Also, the controller 70 may turn on all stages 0 through n header transistors (of header switch 10A) at one time (without sequentially turning them on in stages). The latency of having to turn on one stage and wait before turning on subsequent stages is removed, and the residual power/charge on the decoupling capacitors 15A and 15B are efficiently recycled and shared.

At this point the circuit 115A is charged to Vdd, and the decoupling capacitors 15A and 15B are also charged to Vdd. Now, the controller 70 turns off the coupling element 50, which leaves decoupling capacitor 15B floating while being charged to the voltage level of Vdd (i.e., because both coupling elements 50 and 52 are turned off).

At this point, the circuit 115A is running, and the controller 70 is also configured to wake up the circuit 115B from its power gated state by first pre-charging the circuit 115B. When the controller 70 is ready to turn on (wake up) the circuit 115B and/or predicts that it is soon time, the decoupling capacitor 15B still has its charge, which is ½ Vdd because part of the charge has been taken by circuit 115A. While the header switch 10B and the coupling element 50 both remain off, the controller 70 is configured to turn on coupling element 52 to pre-charge the circuit 115B. As discussed above, turning on coupling element 52 causes current to flow from decoupling capacitor 15B to circuit 115B such that circuit 115B (e.g., internal capacitance) is charged. Since, as a result precharging decoupling capacitance 15B to VDD when powering up circuit 115A, the decoupling capacitor 15B is charged to Vdd, the decoupling capacitor 15B charges (i.e., pre-charges) the circuit 115B to ½ Vdd, all of which occurs before the header switch 10B connects the circuit 115B to the voltage source 120.

Since the circuit 115B has been pre-charged to ½ Vdd by taking charge from the decoupling capacitor 15B, the controller 70 may only turn on stage n header transistor of header switch 10B and/or may turn on all stages 0 through n header transistors (of header switch 10B) at one time (without sequentially turning them on in stages).

When both circuits 115A and 115B are up and running (which means that header switches 10A and 10B are both turned on in order to respectively connect circuits 115A and 115B to the common voltage source 120), the controller 70 may be configured to turn on coupling element 50. Having coupling element 50 turned on allows circuits 115A and 115B to share the two decoupling capacitors 15A and 15B, which helps to reduce noise (such as reduce voltage spikes). It is assumed that both circuits 115A and 115B are operating at the same voltage.

Scenario 3

This scenario begins after the circuit 115A has been pre-charged by both decoupling capacitors 15A and 15B, when coupling elements 50 and 51 have been turned on, and when coupling element 52 is turned off. Also, stage 0 through stage n header transistors of header switch 10A are turned on to connect voltage source 120 to the circuit 115A (i.e., circuit 115A is running). Since coupling elements 50 and 51 are turned on, both decoupling capacitors 15A and 15B are charged back to voltage Vdd from voltage source 120. After the circuit 115A is running, the coupling element 50 remains on to charge decoupling capacitor 15B (when circuit 115B is power gated (i.e., turned off)).

At this point, the circuit 115A is running, and the controller 70 is configured to wake up the circuit 115B from its power gated state by first pre-charging the circuit 115B. When the controller 70 is ready to turn on (wake up) the circuit 115B and/or predicts that it is soon time, the decoupling capacitors 15A and 15B have been charged back up to voltage Vdd. The controller 70 has the first option of using only decoupling capacitor 15B to pre-charge the circuit 115B and/or the second option of using both decoupling capacitors 15A and 15B to pre-charge the circuit 115B.

For the first option, the header switch 10B is still turned off. The controller is configured to turn off the coupling element 50 which leaves the decoupling capacitor 15B floating. Notice that turning off at least one of the coupling elements 50 and 51 is essential for avoiding the voltage noise in the circuit 115A due to the power up of the circuit 115B. The controller 70 turns on the coupling element 52 to connect the decoupling capacitor 15B to the circuit 115B, such that current from decoupling capacitor 15B charges the circuit 115B to ½ Vdd (assuming for illustration purposes that the values of the decoupling capacitances 15A and 15B and the values of the internal circuit capacitances 115A and 115B are all equal). All of this occurs before the header switch 10B connects the circuit 115B to the voltage source 120. Since the circuit 115B has been pre-charged to ½ Vdd by taking charge from the decoupling capacitor 15B, the controller 70 may only turn on stage n header transistor of header switch 10B and/or may turn on all stages 0 through n header transistors (of header switch 10B) at one time (without sequentially turning them on in stages). Also, the controller 70 can turn on coupling element 50 in order for circuits 115A and 115B to share decoupling capacitors 15A and 15B.

For the second option, the header switch 10B is still turned off. The controller is configured to turn off the coupling element 51 and leave the coupling element 50 turned on. This leaves the decoupling capacitors 15A and 15B floating. The controller 70 turns on the coupling element 52 to connect both decoupling capacitors 15A and 15B to the circuit 115B, such that current from decoupling capacitors 15A and 15B charges the circuit 115B to ⅔ Vdd. Using both capacitors 15A and 15B for pre-charging is faster than using a single capacitor. All of this occurs before the header switch 10B connects the circuit 115B to the voltage source 120. Since the circuit 115B has been pre-charged to ⅔ Vdd by taking charge from both decoupling capacitors 15A and 15B, the controller 70 may only turn on stage n header transistor of header switch 10B and/or may turn on all stages 0 through n header transistors (of header switch 10B) at one time (without sequentially turning them on in stages). After both circuits 115A and 115B have been powered-up, the controller 70 can turn on coupling element 50 in order for circuits 115A and 115B to share decoupling capacitors 15A and 15B.

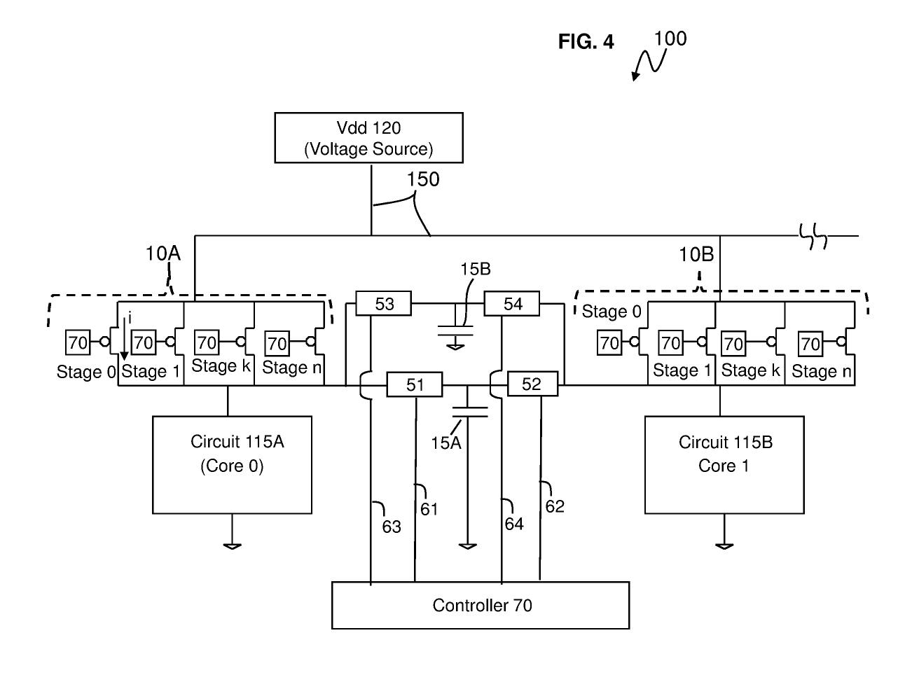

Turning to FIG. 4, FIG. 4 illustrates another example of the circuits 115A and 115B sharing and recycling power in the integrated circuit 100 according to an embodiment. In FIG. 4, the integrated circuit 100 now includes coupling elements 53 and 54 in addition to coupling elements 51 and 52. Coupling element 50 is removed.

In FIG. 4, turning on coupling element 51 connects the circuit 115A to the decoupling capacitor 15A, and turning on the coupling element 52 connects the circuit 115B to the decoupling capacitor 15A. Turning on coupling element 53 connects decoupling capacitor 15B to the circuit 115A, and turning on coupling element 54 connects decoupling capacitor 15B to the circuit 115B.

The controller 70 is configured to turn the coupling element 53 on (i.e., activates) and off (i.e., deactivates) via a control signal 63 (which can provide gate voltage to turn on the transistor 53). Similarly, the controller 70 is configured to turn the coupling element 54 on (i.e., activates) and off (i.e., deactivates) via a control signal 64 (which can provide gate voltage to turn on the transistor 54).

The scenarios discussed above for FIG. 3 apply by analogy to FIG. 4, and are repeated below as scenarios 1A, 2A, and 3A to correspond to scenarios 1, 2, and 3 discussed above. As in scenarios 2 and 3, for illustration purposes it is assumed that the values of the decoupling capacitances in capacitors 15A and 15B and the values of the internal circuit capacitances in circuits 115A and 115B are all equal.

Assume that both decoupling capacitors 15A and 15B are charged to voltage Vdd and both circuits 115A and 115B are power gated. The shared decoupling capacitors 15A and 15B can both and separately be connected (by controller 70) to circuit 115A, circuit 115B, and/or both circuits 115A and 115B through coupling elements 51, 52, 53, and 54.

Scenario 1A

When the controller 70 is ready to turn on (wake up) the circuit 115A and/or predicts that it is soon time, the decoupling capacitor 15A still has its charge. While the header switch 10A, the coupling element 52, the coupling element 53, the coupling element 54 all remain off, the controller 70 is configured to turn on coupling element 51 (optionally the coupling element 53 may also be turned on) to pre-charge the circuit 115A. This is considered pre-charging the circuit 115A, because the header switch 10A has not been turned on to connect the circuit 115A to the common voltage source 120. Turning on coupling element 51 causes current to flow from decoupling capacitor 15A to circuit 115A such that circuit 115A (e.g., internal capacitance) is charged. When decoupling capacitor 15A is charged to voltage Vdd, the decoupling capacitor 15A charges (i.e., pre-charges) the circuit 115A to ½ Vdd which is before the header switch 10A connects the circuit 115A to the voltage source 120.

Since the circuit 115A has been pre-charged to ½ Vdd by taking charge from the decoupling capacitor 15A, the controller 70 may only turn on stage n header transistor (which is the largest transistor) of header switch 10A without having to traverse through turning on the lower stages (i.e., without having to sequentially turn on stage 0 through stage k header transistors before then turning on stage n header transistor). Also, the controller 70 may turn on all stages 0 through n header transistors (of header switch 10A) at one time (without sequentially turning them on in stages). The latency of having to turn on one stage at a time and wait before turning on subsequent stages is removed, and the residual power/charge on the decoupling capacitor 15A is efficiently recycled and shared.

Now, the circuit 115A is running, and the controller 70 is also configured to wake up the circuit 115B from its power gated state by first pre-charging the circuit 115B. When the controller 70 is ready to turn on (wake up) the circuit 115B and/or predicts that it is soon time, the decoupling capacitor 15B still has its (full) charge. While the header switch 10B, the coupling element 52, and coupling element 53 all remain off, the controller 70 is configured to turn on coupling element 54 to pre-charge the circuit 115B. This is considered pre-charging the circuit 115B, because the header switch 10B has not been turned on to connect the circuit 115B to the common voltage source 120. Turning on coupling element 54 causes current to flow from decoupling capacitor 15B to circuit 115B such that circuit 115B (e.g., internal capacitance) is charged. When decoupling capacitor 15B is charged to voltage Vdd, the decoupling capacitor 15B charges (i.e., pre-charges) the circuit 115B to ½ Vdd which is before the header switch 10B connects the circuit 115B to the voltage source 120.

Since the circuit 115B has been pre-charged to ½ Vdd by taking charge from the decoupling capacitor 15B, the controller 70 may only turn on stage n header transistor (which is the largest transistor) of header switch 10B without having to traverse through turning on the lower stages (i.e., without having to sequentially turn on stage 0 through stage k header transistors before then turning on stage n header transistor). Also, the controller 70 may turn on all stages 0 through n header transistors (of header switch 10B) at one time (without sequentially turning them on in stages). The latency of having to turn on one stage and wait before turning on subsequent stages is removed, and the residual power/charge on the decoupling capacitor 15B is efficiently recycled and shared.

Scenario 2A

In this scenario, current is taken from both decoupling capacitors 15A and 15B to charge the circuit 115A. For example, when the controller 70 is ready to turn on (wake up) the circuit 115A and/or predicts that it is soon time (the circuit 115B is turned off), the decoupling capacitors 15A and 15B still have their respective (full) charge. In this case, the header switch 10A, coupling element 52 and coupling element 54 are all turned off, and the controller 70 is configured to turn on coupling element 51 and coupling element 53 to pre-charge the circuit 115A. Again, the header switch 10A has not been turned on to connect the circuit 115A to the common voltage source 120. Turning on coupling element 51 connects the circuit 115A to the decoupling capacitor 15A, and turning on coupling element 53 also connects decoupling capacitor 15B to the circuit 115A. (Note that in scenario 1 only decoupling capacitor 15A was connected to the circuit 115A.) Turning on coupling elements 51 and 53 cause current to flow from both decoupling capacitors 15A and 15B to circuit 115A such that circuit 115A (e.g., internal capacitance) is charged. When decoupling capacitors 15A and 15B are both the same size and charged to voltage Vdd, the decoupling capacitors 15A and 15B charge (i.e., pre-charges) the circuit 115A to ⅔ Vdd all of which occurs before the header switch 10A connects the circuit 115A to the voltage source 120. The circuit 115A has wakened up part of the way.

Now, the controller 70 turns off the coupling elements 51 and 53 (after the decoupling capacitances of capacitors 15A and 15B have been recharged to full Vdd), which leaves decoupling capacitor 15B floating (i.e., because coupling elements 53 and 54 are turned off). Notice that turning off both of the coupling elements 51 and 53 is essential for avoiding the voltage noise in the circuit 115A due to the power up of the circuit 115B.

Since the circuit 115A has been pre-charged to ⅔ Vdd by taking charge from both the decoupling capacitors 15A and 15B, the controller 70 may only turn on stage n header transistor (which is the largest transistor) of header switch 10A without having to traverse through turning on the lower stages (i.e., without having to sequentially turn on stage 0 through stage k header transistors before then turning on stage n header transistor). Also, the controller 70 may turn on all stages 0 through n header transistors (of header switch 10A) at one time (without sequentially turning them on in stages). The latency of having to turn on one stage and wait before turning on subsequent stages is removed, and the residual power/charge on the decoupling capacitors 15A and 15B are efficiently recycled and shared.

At this point, the circuit 115A is running, and the controller 70 is also configured to wake up the circuit 115B from its power gated state by first pre-charging the circuit 115B. When the controller 70 is ready to turn on (wake up) the circuit 115B and/or predicts that it is soon time, the decoupling capacitors 15A and 15B still hold their charge, which is Vdd because they were precharged to Vdd when powering up circuit 115A. While the header switch 10B, the coupling element 51, and the coupling element 53 are turned off, the controller 70 is configured to turn on coupling elements 52 and 54 to pre-charge the circuit 115B. Turning on coupling elements 52 and 54 causes current to flow from decoupling capacitors 15A and 15B to circuit 115B such that circuit 115B (e.g., internal capacitance) is charged. Since decoupling capacitors 15A and 15B is charged to voltage Vdd, the decoupling capacitors 15A and 15B charge (i.e., pre-charge) the circuit 115B to ⅔ Vdd all of which occurs before the header switch 10B connects the circuit 115B to the voltage source 120.

Since the circuit 115B has been pre-charged to ⅔ Vdd by taking charge from the decoupling capacitor 15B, the controller 70 may only turn on stage n header transistor of header switch 10B and/or may turn on all stages 0 through n header transistors (of header switch 10B) at one time (without sequentially turning them on in stages).

When both circuits 115A and 115B are up and running (which means that header switches 10A and 10B are both turned on in order to respectively connect circuits 115A and 115B to the common voltage source 120), the controller 70 is configured to turn on coupling elements 51, 52, 53, and 54. Having coupling elements 51, 52, 53, and 54 turned on allows circuits 115A and 115B to share the two decoupling capacitors 15A and 15B, which helps to reduce noise (such as reduce voltage spikes). It is assumed that both circuits 115A and 115B are operating at the same voltage.

Scenario 3A

This scenario begins after the circuit 115A has been pre-charged by both decoupling capacitors 15A and 15B, when coupling elements 51 and 53 have been turned on and coupling elements 52 and 54 are turned off. Also, stage 0 through stage n header transistors of header switch 10A are turned on to connect voltage source 120 to the circuit 115A (i.e., circuit 115A is running). Since coupling elements 51 and 53 are turned on, both decoupling capacitors 15A and 15B are charged back to voltage Vdd from voltage source 120. After the circuit 115A is running, the coupling element 53 remains on to charge decoupling capacitor 15B (when circuit 115B is power gated (i.e., turned off)).

At this point, the circuit 115A is running, and the controller 70 is configured to wake up the circuit 115B from its power gated state by first pre-charging the circuit 115B. When the controller 70 is ready to turn on (wake up) the circuit 115B and/or predicts that it is soon time, the decoupling capacitors 15A and 15B have been charged back up to voltage Vdd. The controller 70 has the first option of using only decoupling capacitor 15B to pre-charge the circuit 115B and/or the second option of using both decoupling capacitors 15A and 15B to pre-charge the circuit 115B.

For the first option, the header switch 10B is still turned off. The controller 70 is configured to turn off the coupling element 53 which leaves the decoupling capacitor 15B floating. The controller 70 turns on the coupling element 54 to connect the decoupling capacitor 15B to the circuit 115B, such that current from decoupling capacitor 15B charges the circuit 115B to ½ Vdd. All of this occurs before the header switch 10B connects the circuit 115B to the voltage source 120. Since the circuit 115B has been pre-charged to ½ Vdd by taking charge from the decoupling capacitor 15B, the controller 70 may only turn on stage n header transistor of header switch 10B and/or may turn on all stages 0 through n header transistors (of header switch 10B) at one time (without sequentially turning them on in stages). Also, the controller 70 can turn on coupling elements 52 and 53 in order for circuits 115A and 115B to share decoupling capacitors 15A and 15B.

For the second option, the header switch 10B is still turned off. The controller 70 is configured to turn off the coupling elements 51 and 53. This leaves the decoupling capacitors 15A and 15B floating (because coupling elements 52 and 54 are not yet turned on). The controller 70 turns on the coupling elements 52 and 54 to connect both decoupling capacitors 15A and 15B to the circuit 115B, such that current from decoupling capacitors 15A and 15B charges the circuit 115B to ½ Vdd. Using both capacitors 15A and 15B for pre-charging is faster than using a single capacitor. All of this occurs before the header switch 10B connects the circuit 115B to the voltage source 120. Since the circuit 115B has been pre-charged to ½ Vdd by taking charge from both decoupling capacitors 15A and 15B, the controller 70 may only turn on stage n header transistor of header switch 10B and/or may turn on all stages 0 through n header transistors (of header switch 10B) at one time (without sequentially turning them on in stages). Also, the controller 70 can turn on coupling elements 51 and 53 in order for circuits 115A and 115B to share decoupling capacitors 15A and 15B.

Note that various examples are provided when circuit 115A is turned on (i.e., wakes up) before circuit 115B (for consistency in explanation). Embodiments are not meant to be limited, and the explanation applies by analogy to turning on circuit 115B before turning on circuit 115A.

As one implementation, the coupling elements 50, 51, 52, 53, and 54 may each be transistors with their respective gates connected to and controlled by the controller 70. As one example, the transistors (i.e., coupling elements) may be metal oxide semiconductor field effect transistors (MOSFET). It is understood that other types of transistors may be utilized.

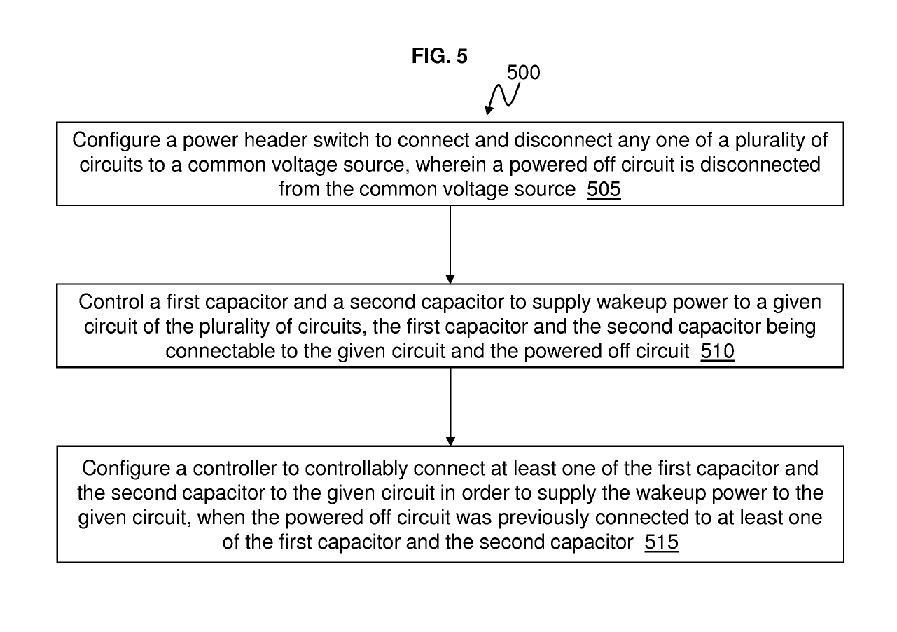

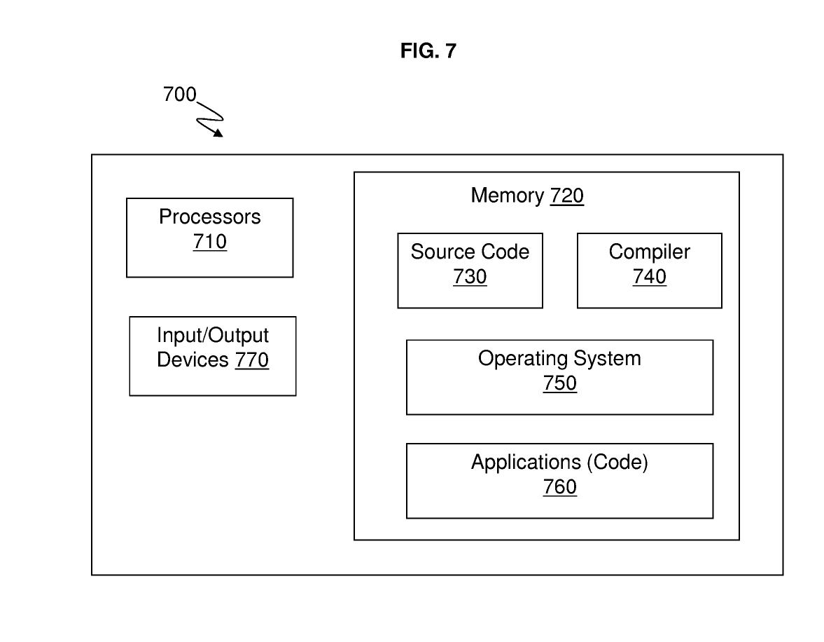

Now turning to FIG. 5, a method 500 is illustrated for operating an integrated circuit 100 with power gating according to an embodiment. Reference can be made to FIGS. 1-4 (along with FIG. 7 discussed below).

The controller 70 is configured to connect and/or disconnect a power header switch (e.g., header switches 10A and 10B) to any one of a plurality of circuits (e.g., circuits 115A and 115B) to the common voltage source 120 at block 505. A power off circuit 115B is just disconnected (e.g., 1 to 10 seconds) from the common voltage source 120.

The controller 70 is configured to control a first capacitor (e.g., decoupling capacitor 15A) and a second capacitor (e.g., decoupling capacitor 15B) to supply wakeup power to a given circuit (e.g., circuit 115A) of the plurality of circuits in which the first capacitor and the second capacitor are connectable to the given circuit (e.g., via coupling elements 50, 51, and/or 53 for circuit 115A) and the powered off circuit (via coupling elements 50, 52, and/or 54 for circuit 115B) at block 510.

At block 515, the controller 70 is configured to controllably connect the first capacitor 15A and/or the second capacitor 15B to the given circuit 115A in order to supply wakeup power to the given circuit 115A, when the powered off circuit 115B was (recently) previously connected to at least one of the first capacitor 15A and/or the second capacitor 15B.

The first capacitor 15A and/or the second capacitor 15B are charged by having been previously connected to the powered off circuit 115B before the powered off circuit 115B is disconnected from the common voltage source 120.

The given circuit 115A is disconnected from the common voltage source 120 when the first capacitor 15A and/or the second capacitor 15B supply the wakeup power to the given circuit 115A. Supplying the wakeup power to the given circuit 115A transfers current from the first capacitor 15A and/or the second capacitor 15B to the given circuit 115A. The power header switch 10A for the given circuit 115A is turned on to connect the given circuit 115A to the common voltage source 120 based on the first capacitor 15A and/or the second capacitor 15B having supplied the wakeup power to pre-charge the given circuit 115A. The power header switch 10A for the given circuit 115A is turned on as a single header transistor (e.g., stage 0 through stage n at one time or only stage n), in which the single header transistor does not require a sequence of (stage 0 through stage n) header transistors to consecutively turn on before the power header switch 10A supplies full current from the common voltage source 120 to the given circuit 115A.

When the controller 70 determines that another given circuit 115B, previously the powered off circuit, is to be awaken, the controller 70 is configured to disconnect the first capacitor 15A and/or the second capacitor 15B from the given circuit 115A (now connected to the common voltage source 120). The controller 70 is configured to controllably connect the first capacitor 15A and/or the second capacitor 15B to the other given circuit 115B in order to supply the wakeup power to the given circuit 115B, when the given circuit 115A has been disconnected from the first capacitor 15A and/or the second capacitor 15B.

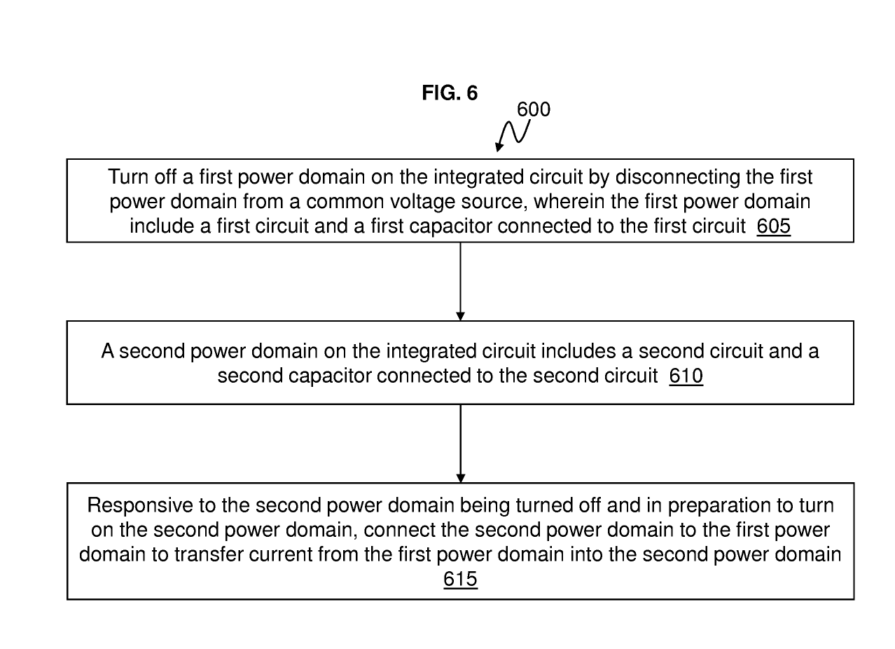

Turning to FIG. 6, a method 600 is illustrated for operating the integrated circuit 100 with power gating according to an embodiment. Reference can be made to FIGS. 1-4 (along with FIG. 7 discussed below).

At block 605, the controller 70 is configured to turn off a first power domain on the integrated circuit 100 by disconnecting the first power domain from the common voltage source 120, in which the first power domain includes a first circuit 115A and a first capacitor 15A connected to the first circuit 115A.

A second power domain on the integrated circuit 100 includes a second circuit 115B and a second capacitor 15B connected to the second circuit at block 610.

Responsive to the second power domain already being turned off (i.e., power gated) and in preparation to turn on (wake up) the second power domain, the controller 70 is configured to connect (via coupling element 50 in FIG. 2, via coupling elements 50 and 51 in FIG. 3, and/or via coupling elements 51, 52, 53, and 54 in FIG. 4) the second power domain to the first power domain to transfer current from the first power domain (from circuit 115A and decoupling capacitor 15A) into the second power domain at block 615.

The second power domain is connected to the first power domain before the current leaks out of the first power domain. The controller 70 is configured to turn on the coupling element(s) to connect the second power domain to the first power domain. Connecting the second power domain to the first power domain to transfer current from the first power domain into the second power domain comprises disconnecting the first circuit 115A from the first power domain (i.e., from capacitor 15A), and (then only) connecting the first capacitor 15A to the second power domain (circuit 115B and capacitor 15B) such that the current is transferred from the first capacitor 15A to the second power domain, while the first circuit 115A is disconnected.

Now turning to FIG. 7, an example illustrates a computer 700 (e.g., any type of computer system that includes and/or operates one or more integrated circuits 100) that may implement features discussed herein. The computer 700 may be a distributed computer system over more than one computer. Various methods, procedures, modules, flow diagrams, tools, applications, circuits, elements, and techniques discussed herein may also incorporate and/or utilize the capabilities of the computer 700. Indeed, capabilities of the computer 700 may be utilized to implement features of exemplary embodiments discussed herein.

Generally, in terms of hardware architecture, the computer 700 may include one or more processors 710, computer readable storage memory 720, and one or more input and/or output (I/O) devices 770 that are communicatively coupled via a local interface (not shown). The local interface can be, for example but not limited to, one or more buses or other wired or wireless connections, as is known in the art. The local interface may have additional elements, such as controllers, buffers (caches), drivers, repeaters, and receivers, to enable communications. Further, the local interface may include address, control, and/or data connections to enable appropriate communications among the aforementioned components.

The processor 710 is a hardware device for executing software that can be stored in the memory 720. The processor 710 can be virtually any custom made or commercially available processor, a central processing unit (CPU), a data signal processor (DSP), or an auxiliary processor among several processors associated with the computer 700, and the processor 710 may be a semiconductor based microprocessor (in the form of a microchip) or a macroprocessor.

The computer readable memory 720 can include any one or combination of volatile memory elements (e.g., random access memory (RAM), such as dynamic random access memory (DRAM), static random access memory (SRAM), etc.) and nonvolatile memory elements (e.g., ROM, erasable programmable read only memory (EPROM), electronically erasable programmable read only memory (EEPROM), programmable read only memory (PROM), tape, compact disc read only memory (CD-ROM), disk, diskette, cartridge, cassette or the like, etc.). Moreover, the memory 720 may incorporate electronic, magnetic, optical, and/or other types of storage media. Note that the memory 720 can have a distributed architecture, where various components are situated remote from one another, but can be accessed by the processor(s) 710.

The software in the computer readable memory 720 may include one or more separate programs, each of which comprises an ordered listing of executable instructions for implementing logical functions. The software in the memory 720 includes a suitable operating system (0/S) 750, compiler 740, source code 730, and one or more applications 760 of the exemplary embodiments. As illustrated, the application 760 comprises numerous functional components for implementing the features, processes, methods, functions, and operations of the exemplary embodiments.

The operating system 750 may control the execution of other computer programs, and provides scheduling, input-output control, file and data management, memory management, and communication control and related services.

The application 760 may be a source program, executable program (object code), script, or any other entity comprising a set of instructions to be performed. When a source program, then the program is usually translated via a compiler (such as the compiler 740), assembler, interpreter, or the like, which may or may not be included within the memory 720, so as to operate properly in connection with the O/S 750. Furthermore, the application 760 can be written as (a) an object oriented programming language, which has classes of data and methods, or (b) a procedure programming language, which has routines, subroutines, and/or functions.

The I/O devices 770 may include input devices (or peripherals) such as, for example but not limited to, a mouse, keyboard, scanner, microphone, camera, etc. Furthermore, the I/O devices 770 may also include output devices (or peripherals), for example but not limited to, a printer, display, etc. Finally, the I/O devices 770 may further include devices that communicate both inputs and outputs, for instance but not limited to, a NIC or modulator/demodulator (for accessing remote devices, other files, devices, systems, or a network), a radio frequency (RF) or other transceiver, a telephonic interface, a bridge, a router, etc. The I/O devices 770 also include components for communicating over various networks, such as the Internet or an intranet. The I/O devices 770 may be connected to and/or communicate with the processor 710 utilizing Bluetooth connections and cables (via, e.g., Universal Serial Bus (USB) ports, serial ports, parallel ports, FireWire, HDMI (High-Definition Multimedia Interface), etc.).

In exemplary embodiments, where the application 760 is implemented in hardware, the application 760 can be implemented with any one or a combination of the following technologies, which are each well known in the art: a discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated

The flow diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

1. An integrated circuit with power gating, the integrated circuit comprising:
a power header switch configured to connect and disconnect any one of a plurality of circuits to a common voltage source, wherein a powered off circuit in the plurality of circuits is disconnected from the common voltage source;
a first capacitor and a second capacitor configured to supply wakeup electrical charge to a given circuit of the plurality of circuits, the first capacitor and the second capacitor being connectable to the given circuit and the powered off circuit; and
a controller configured to controllably connect at least one of the first capacitor and the second capacitor to the given circuit in order to supply the wakeup electrical charge to the given circuit, in response to the powered off circuit being previously connected to at least one of the first capacitor and the second capacitor.

2. The integrated circuit of claim 1, wherein the at least one of the first capacitor and the second capacitor are charged by having been connected to the powered off circuit before the powered off circuit is disconnected from the common voltage source.

3. The integrated circuit of claim 1, wherein the given circuit is disconnected from the common voltage source when the at least one of the first capacitor and the second capacitor supply the wakeup electrical charge to the given circuit.

4. The integrated circuit of claim 1, wherein supplying the wakeup electrical charge to the given circuit transfers the wakeup electrical charge from the at least one of the first capacitor and the second capacitor to the given circuit.

5. The integrated circuit of claim 1, wherein the power header switch for the given circuit is turned on in a sequence of stages to connect the given circuit to the common voltage source where the sequence is based on the at least one of the first capacitor and the second capacitor having previously supplied the wakeup electrical charge to pre-charge the given circuit.

6. The integrated circuit of claim 5, wherein all stages of the power header switch for the given circuit are turned on as a single header transistor, in which the single header transistor does not require a sequence of header transistors to consecutively turn on before the power header switch supplies full current from the common voltage source to the given circuit.

7. The integrated circuit of claim 1, wherein when the controller determines that another given circuit, previously the powered off circuit, is to be awaken, the controller is configured to disconnect the at least one of the first capacitor and the second capacitor from the given circuit in order to prevent a discharge of capacitance.

8. The integrated circuit of claim 7, wherein the controller is configured to controllably connect the at least one of the first capacitor and the second capacitor to the another given circuit in order to supply the wakeup electrical charge to the another given circuit, when the given circuit is disconnected from the at least one of the first capacitor and the second capacitor.

9. The integrated circuit of claim 1, wherein power dissipated for waking up powered off circuits is reduced and a latency of waking up the powered off circuits is reduced by the controller controllably connecting at least one of the first capacitor and the second capacitor to the given circuit to supply the wakeup electrical charge.

10-20. (canceled)
